(19) United States
(12) Patent Application Publication
(10) Pub. No.: US 2019/0335606 A1
(43) Pub. Date: Oct. 31, 2019

(54) UNIVERSAL POWER SUPPLY

(71) Applicant: Microsoft Technology Licensing, LLC, Redmond, WA (US)

(72) Inventors: Sean M. James, Olympia, WA (US); Christian L. Belady, Mercer Island, WA (US); Shaun Harris, Burton, TX (US)

(21) Appl. No.: 15/963,222

(22) Filed: Apr. 26, 2018

(51) Int. Cl. H05K 7/14; H05K 7/20

(52) U.S. Cl. CPC H05K 7/1492; H05K 7/209; H05K 7/20709

(57) ABSTRACT

According to some embodiments, a power supply component for a computer server may include a physical input receptacle adapted to receive with of an Alternating Current (“AC”) plug and a Direct Current (“DC”) plug. An AC-to-DC rectifier circuit coupled to the physical input receptacle may convert AC current into DC current when AC current is received via the physical input receptacle. The power supply component may also include a DC-to-DC voltage regulator to reduce voltages swings. The power supply component might be associated with, for example, a computer data center.

### BACKGROUND

Note that a system, such as a computer data center, might be associated with a wide variety of power generation sources such as an electric utility, backup generators, batteries, alternators, fuel cells, etc. and each may supply different forms of electricity. This can complicate the configuration of computer equipment. For example, if a data center has a Direct Current (“DC”) source at one location an Alternating Current (“AC”) source at another location, the enterprise may need to maintain two different kinds of computer equipment. If a power source is DC, a technician may need to install an inverter and voltage regulator. If a power source is AC, the technician may need to install a rectifier. Such additional power conversion equipment can reduce efficiency and increase the need for the enterprise to maintain different types equipment, ensure the availability of appropriate spare parts, provide training for technicians, etc.

What is needed is a power supply that reduces the need for additional equipment to handle different types of power sources.

### BRIEF DESCRIPTION OF THE DRAWINGS

FIG. 1 is a high-level block diagram of a system according to some embodiments.

FIG. 2 illustrates one example system implementing a rack-based power supply in accordance with some embodiments.

FIG. 3 is a block diagram illustrating an example rack power unit according to some embodiments.

FIG. 4 is a flow diagram of a process using a universal power supply in accordance with some embodiments.

FIG. 5 illustrates a physical input receptacle for a universal power supply according to some embodiments.

FIG. 6 is a more detailed block diagram of a system according to some embodiments.

FIG. 7 illustrates an example rack power unit in accordance with some embodiments.

FIG. 8 illustrates an example rack assemble for a computer data center according to some embodiments.

### DETAILED DESCRIPTION

The following description is provided to enable any person in the art to make and use the described embodiments. Various modifications, however, will remain readily apparent to those in the art.

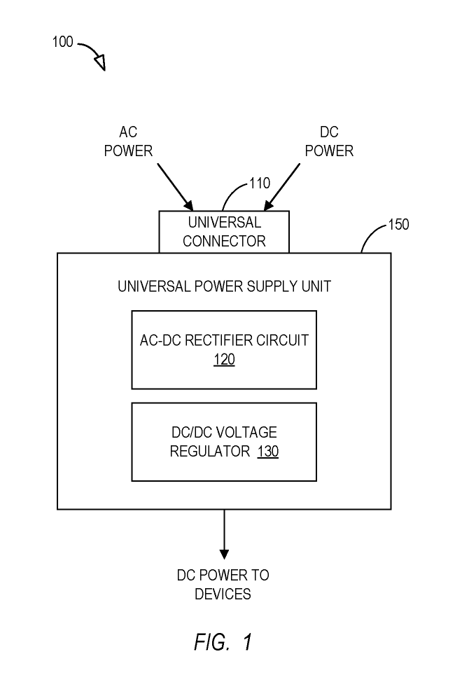

Generally, some embodiments provide a power supply that reduces the need for additional equipment to handle different types of power sources. FIG. 1 is a high-level block diagram of a system 100 according to some embodiments. The system 100 includes a power supply component 150, such as a power supply for a computer server at a computer data center. The power supply component 150 includes a universal connector 110, such as a physical input receptacle adapted to receive either of both an AC plug and a DC plug. A received AC plug might provide power from an electric utility, such as power from substantially 200 Volts (“V”) to substantially 240 V at a frequency of from substantially 50 Hertz (“Hz”) to substantially 60 Hz. A received DC plug might provide power from a battery or DC fuel cell. According to some embodiments, the universal connector 110 is adapted to prevent reverse polarization.

The power supply component 150 also includes an AC-to-DC rectifier circuit 120 coupled to the universal connector 110 to convert AC current into DC current when AC current is received via the universal connector. For example, the AC-to-DC rectifier circuit 120 may sense a lack of AC and allows DC to bypass the rectifier circuit. According to some embodiments, the power supply component 150 also includes a DC-to-DC voltage regulator 139 to reduce voltages swings. For example, the DC-to-DC voltage regulator 130 may accommodates voltage swings from a DC source as more current is drawn (e.g., the DC-to-DC rectifier may let the power supply component 150 utilize DC voltages that decrease as more current is drawn).

Some embodiments described herein may be associated with a universal power supply for a computer data center. Note that a data center may include multiple computing devices and optionally other networking devices that are located within a device rack. AC or DC power might be provided to the data center from an external power source, batteries, DC fuel cells, a local backup generator in the event of a loss of power from the external power source, etc.

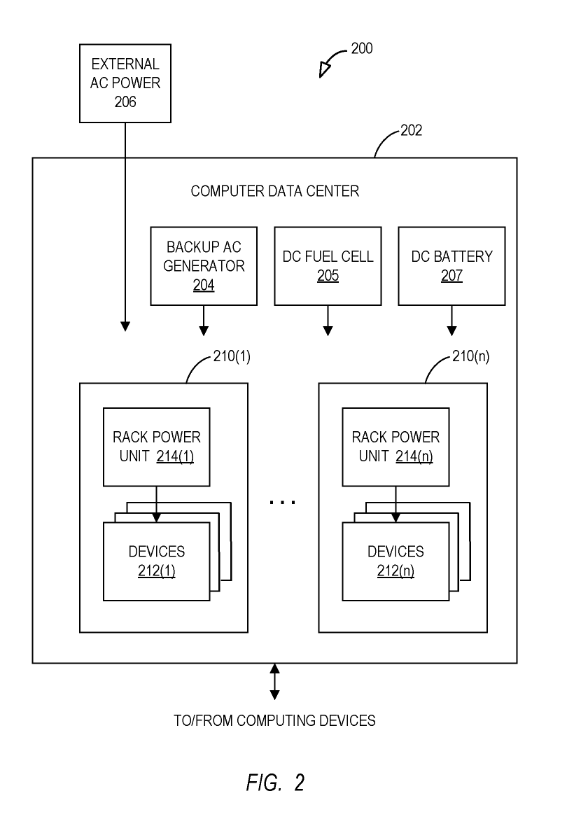

FIG. 2 illustrates an example system 200 implementing a rack-based universal power supply in accordance with one or more embodiments. The system 200 includes a data center 202, a backup generator 204, external AC power 206 received from an external power source, a DC fuel cell, and a DC batter 207. The data center 202 may include one or more (n) device racks 210(1), . . . , 210(n), each including one or more devices 212 and a rack power unit 214. The device racks 210 are also referred to as simply racks. Although reference is made herein to device racks, it should be noted that devices 212 and power units 214 can alternatively be grouped into other containers, mounting units, or other grouping configurations. In such situations, the rack-based universal power supply techniques discussed herein can be based on such alternate groupings rather than based on a rack.

The data center 202 operates to provide one or more services to various computing devices. These computing devices can be located in close physical proximity to data center 202, and/or located across a wide geographic range (e.g., throughout a country or throughout the world). The data center 202 can communicate with such computing devices via a variety of different networks, including the Internet, a local area network (“LAN”), a cellular or other phone network, an intranet, other public and/or proprietary networks, combinations thereof, and so forth. The data center 202 can be accessed by a variety of different types of computing devices, such as a desktop computer, a laptop computer, a mobile station, an entertainment appliance, a television, a set-top box communicatively coupled to a display device, a cellular or other wireless phone, a game console, an automotive computer, and so forth.

The data center 202 can provide one or more of a variety of different services to computing devices. For example, the data center 202 can provide one or more of a social networking service, an email service, a search service, an information resource/storage service, a messaging service, an image and/or video sharing service, a gaming or other entertainment service, and so forth. The one or more services provided by data center 202 can be publicly available or alternatively access to one or more of the services can be restricted to particular users (e.g., those having a valid account as verified by a service of data center 202).

In the system 200, external AC power 206 is power received from one or more conventional external power sources, such as a power station managed by a power utility company. The external AC power 206 can be, for example, single-phase or 3-phase power. An interruption in external AC power 206 (also referred to as a power outage) can occur, and refers to a situation where the expected external AC power 206 is not received by data center 202. A variety of causes exist for such an interruption, such as a failure at a power station that provides power 206, a failure in a power transmission line between such a power station and data center 202, and so forth.

The backup generator 204 is a power generator that operates as a backup source of AC power in the event of an interruption in external AC power 206. The backup generator 204 can be, for example, a diesel-powered or gas-powered generator. Although a single backup generator 204 is illustrated in system 200, alternatively multiple backup generators 204 (e.g., each responsible for providing AC power to one or more racks 210) can be included in system 200. The backup generator 204 can provide, for example, single-phase or 3-phase AC power, typically providing the same of single-phase or 3-phase power as external AC power 206. Alternatively, backup generator 204 can provide DC power rather than AC power. Other potential sources of power include the DC fuel cell 205 and the DC battery 207.

Multiple devices 212 in data center 202 operate to provide the functionality of the one or more services provided by the data center 202. A variety of different types of devices can be included as the devices 212. The devices 212 typically include one or more server computers, such as rack servers or blade servers. The devices 212 can also include one or more other components, such as a networking component (e.g., a gateway, a router, a switch, etc.), a data storage component (e.g., one or more magnetic disk drives), a cooling component (e.g., a fan or liquid cooling system), and so forth.

The devices 212 are located within racks 210 of data center 202. A rack 210 is a physical structure or housing into which multiple chassis can be inserted, mounted, or otherwise placed. A rack includes different physical locations where a chassis of a particular size (referred to as a Rack Unit or “RU”) can be placed. Different types of racks 210 can hold different numbers of chassis. For example, a particular rack 210 may be configured to hold 50 chassis, 90 chassis, and so forth. A chassis in turn can house a variety of different components, such as a device 212 or a rack power unit 214. Each rack 210 includes one or more data buses, one or more control buses, and one or more power buses that allow data and control information to be communicated to and from devices 212, and allow power to be communicated to devices 212.

Each rack includes one or more rack power units 214. According to some embodiments, each rack power unit 214 is able to receive either AC or DC power, which can be external AC power 206, AC power from backup generator 204, DC power from the fuel cell 205, etc. If necessary, each rack power unit 214 may convert received AC power into DC power, and provide the DC power to devices 212 within the same rack as that rack power unit. For example, rack power unit 214(1) might provide DC power to devices 212(1) in rack 210(1), but does not provide DC power to devices 212(n) in other racks (n) (e.g., racks in which n is greater than or equal to 2). Additionally, although each rack 210 is illustrated in FIG. 2 as including one rack power unit 214, alternatively a rack 210 can include two or more rack power units that each provide DC power to devices within the same rack as the two or more rack power units. When a rack power unit 214 receives a DC power input, the rack power unit 214 may convert received DC power to a desired voltage (e.g., as desired for a DC power bus within a rack 210).

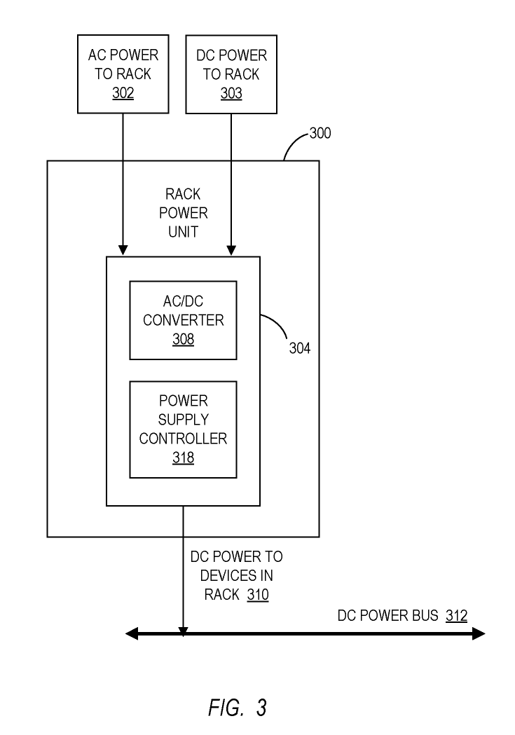

FIG. 3 is a block diagram illustrating an example rack power unit 300 in accordance with one or more embodiments. The rack power unit 300 is an example of a rack power unit 214 of FIG. 2. The rack power unit 300 may receive either AC power 302, which can be from a variety of sources, such as a power station, a backup generator, and so forth and DC power 303 from a battery, fuel cell, etc.

The rack power unit 300 includes one or more universal power supplies 304 and one or more battery packs 306. The number of universal power supplies 304 in a rack power unit 300 can vary. For example, multiple universal power supplies 304 can be included in rack power unit 300 for redundancy (e.g., in the event of a failure of one of the universal power supplies 304).

The universal power supplies 304 may each include an AC/DC converter 308 that receives AC power 302, converts the received AC power to DC power, and provides DC power 310 to the devices in the same rack as rack power unit 300. DC power 310 can be any of a variety of different voltages, such as 22 volts, 34 volts, 48 volts, etc. DC power 310 is provided to the devices in the same rack as rack power unit 300 via a DC power bus 312. Each device in the same rack as rack power unit 300 is coupled to DC power bus 312. Thus, rather than converting received AC power to DC power, each device in the rack receives DC power via bus 312. Each universal power supply 304 may also include a DC power converter that converts DC power 303 received at the universal power supplies 304 to a desired voltage for DC power bus 312.

Each of these devices in the same rack as rack power unit 300 can simply pass through the DC power received via bus 312 to the various components within the devices. Alternatively, if one or more of the components within one or more of the devices desires a different voltage, the device can increase or decrease the DC power received via bus 312. For example, if components within a device desire 34 volts whereas DC power bus 312 provides 22 volts, then a boost power converter can be included in the device to boost the 22 volts to 34 volts within the device. By way of another example, if components within a device desire 22 volts whereas DC power bus 312 provides 34 volts, then a buck converter can be included in the device to reduce the voltage from 34 volts to 22 volts within the device. Similarly, DC power can be provided on DC power bus 312 at a rate below the DC voltage desired by the devices and each device can include a boost power converter to increase the DC power to the voltage level desired within the device. For example, DC power bus 312 can provide 21 volts, and each device can include a boost power converter to boost the 21 volts to 22 volts within the device.

The universal power supplies 304 can also receive control information from devices in the same rack as rack power unit 300 in the form of device feedback. Device feedback can be used to facilitate the operation of power supply 304 in providing DC power 310 to the devices. The rack power unit 300 may be implemented using a single chassis, with the power supply 304 included in that chassis. Alternatively, rack power unit 300 can be implemented across multiple chassis, such as one or more power supplies 304 being implemented in one or more chassis.

In one or more embodiments, DC power bus 312 has multiple ports that are coupled to by the computing devices powered by rack power unit 300 (e.g., bus 312 can have multiple receptacles that are physically plugged into by the devices, or can have multiple cords and plugs that are plugged into receptacles of the devices). A power supply controller 318 can manage these ports individually, allowing DC power to be turned on or turned off to a particular device as desired by the controller 318. The power supply controller 318 can also monitor the power consumed at the power port, and can use the information obtained from this monitoring in different manners, such as determining an average power usage of the device (and thus of the rack that includes rack power unit 300), peak power usage of the device (and thus of the rack that includes rack power unit 300), and so forth.

The rack power unit 300 can be easily removed from a rack and/or changed (e.g., swapped out for a replacement rack power unit 300). This allows rack power units 300 to be replaced (e.g., in the event of failed components in the power unit), to have maintenance easily performed on rack power units 300, and so forth. In situations where the rack power unit 300 is implemented using multiple chassis, such chassis can be easily removed and/or changed individually

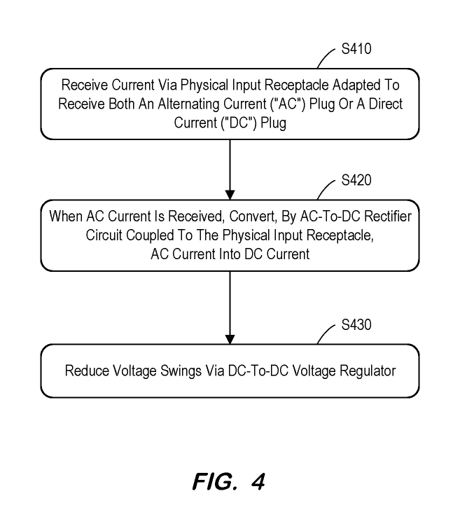

FIG. 4 is a flow diagram of a process using a universal power supply in accordance with some embodiments. The process of FIG. 4 might be associated with, for example, a computer data center. For example, the power supply component might be located within a data center computer server rack. At S410, current is received via a physical input receptacle adapted to receive either of both an AC plug and a DC plug. According to some embodiments, the physical input receptacle is adapted to prevent reverse polarization. For example, the physical input receptacle might be associated with a National Electrical Manufacturers Association (“NEMA”) C19 connector.

When AC current is received via the physical input receptacle, an AC-to-DC rectifier circuit coupled to the physical input receptacle may convert AC current into DC current at S420. For example, the AC-to-DC rectifier circuit may sense a lack of AC and allow DC to bypass the rectifier circuit. At S430, voltage swings may be reduced via a DC-to-DC voltage regulator. For example, the DC-to-DC voltage regulator may accommodate voltage swings from a DC source as more current is drawn.

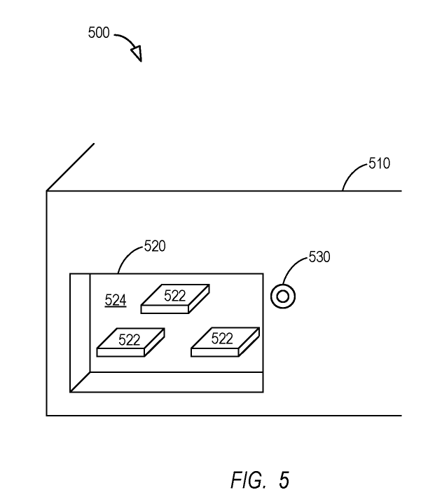

FIG. 5 illustrates a physical input receptacle or connector for a universal power supply 510 according to some embodiments. In particular, the universal power supply 510 includes an AC input portion 520 (to receive AC power) and a DC input portion 530 (to receive DC power). The AC input portion 520 might, according to some embodiments, be associated with a NEMA C19 connector. In such an implementation, the AC input portion 520 might be associated with a defined recess 524 that contains prongs or plugs 522 through which AC power is received. Note that a NEMA C19 connector is adapted to prevent accidental reverse polarization.

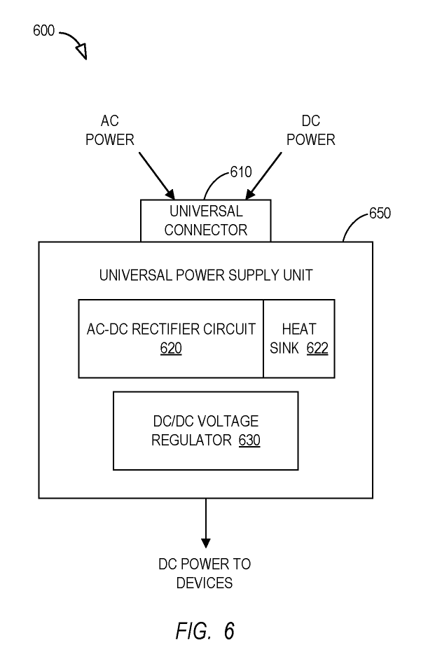

FIG. 6 is a more detailed block diagram of a system 600 according to some embodiments. The system 600 includes a power supply component 650, such as a power supply for a computer server at a computer data center. The power supply component 650 includes a universal connector 610, such as a physical input receptacle adapted to receive either of both an AC plug and a DC plug. A received AC plug might provide power from an electric utility, such as power from substantially 200 V to substantially 240 V at a frequency of from substantially 50 Hz to substantially 60 Hz. A received DC plug might, for example, provide power from a battery or DC fuel cell. According to some embodiments, the universal connector 610 is adapted to prevent accidental reverse polarization (that is, the positive and negative terminals are cannot be connected backwards).

The power supply component 650 also includes an AC-to-DC rectifier circuit 620 coupled to the universal connector 610 to convert AC current into DC current when AC current is received via the universal connector. For example, the AC-to-DC rectifier circuit 620 may sense a lack of AC and allows DC to bypass the rectifier circuit. A heat sink 622 may be positioned proximate to the AC-to-DC rectifier circuit 620 to help dissipate heat generated by the circuit. That is, the AC-to-DC rectifier circuit 620 may have an ability to sense a lack of alternating current and allow the direct current to bypass the rectifier circuit 620 (and the heat sink 622 can help make sure the system 600 can dissipate heat when in VDC mode). According to some embodiments, the AC-to-DC rectifier circuit 620 is associated with a single-phase rectifier (using half-wave rectification or full-wave rectification), a three-phase rectifier (using a half-wave circuit, full-wave circuit using center-tapped transformer, a controlled or uncontrolled three-phase bridge rectifier, etc.), a twelve-pulse bridge rectifier, a voltage-multiplying rectifier, a rectifier that incorporates output smoothing, etc.

According to some embodiments, the power supply component 650 also includes a DC-to-DC voltage regulator 639 to reduce voltages swings. For example, the DC-to-DC voltage regulator 630 may accommodates voltage swings from a DC source as more current is drawn (e.g., the DC-to-DC rectifier may let the power supply component 650 utilize DC voltages that decrease as more current is drawn).

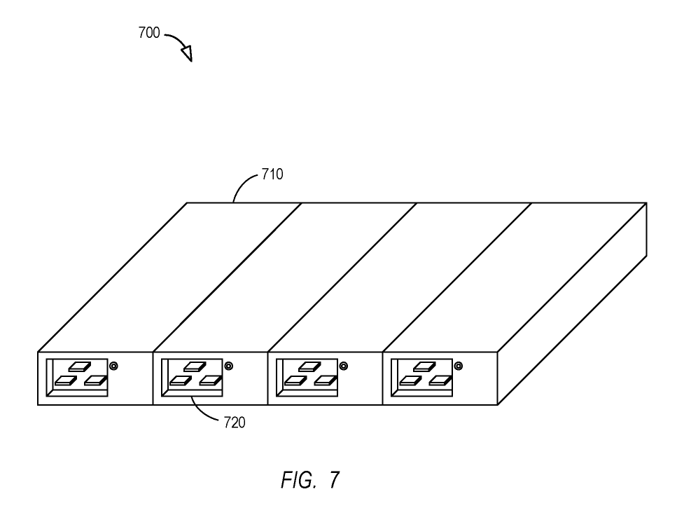

FIG. 7 illustrates an example rack power unit 700 in accordance with one or more embodiments. The rack power unit 700 can be, for example, a rack power unit 200 of FIG. 2 or a rack power unit 114 of FIG. 1. The rack power unit 700 includes four universal power supplies 710, each having a universal connector capable of receiving either an AC or DC power connection. Each universal power supply 702-708 can be, for example, a universal power supply 204 of FIG. 2. Note that various ones of the universal power supplies 710 might be replaceable without powering down rack power unit 700. Although the example rack power unit 700 includes four universal, the rack power unit 700 can include any number of universal power supplies.

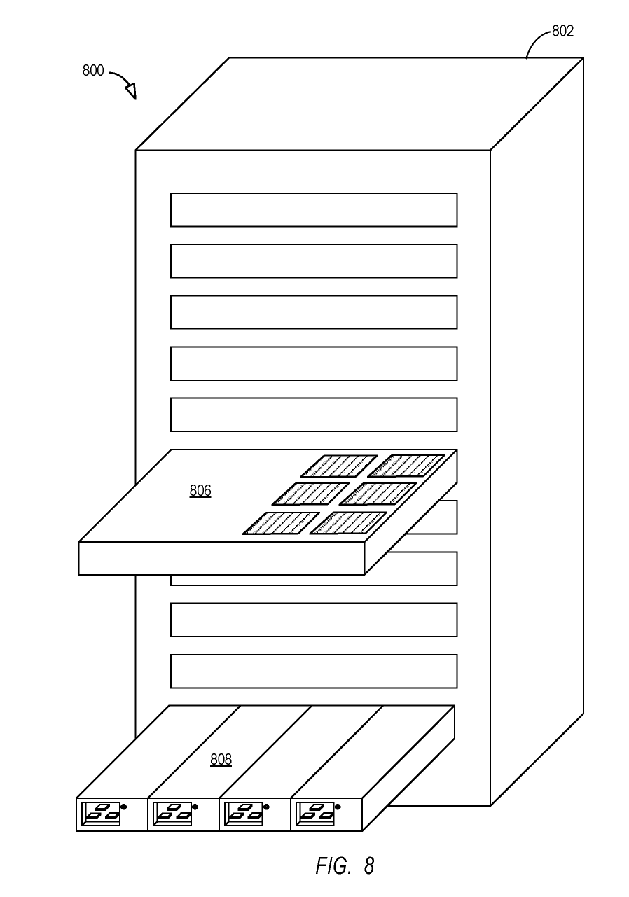

FIG. 8 illustrates an example rack assembly 800 in accordance with one or more embodiments. The rack assembly 800 includes a rack 802 housing multiple devices and/or universal rack power units. The rack 802 can be, for example, a rack 110 of FIG. 1. In the example of FIG. 8, a universal rack power unit 804 and a device 806 are illustrated in additional detail and removed from the rack 802, and each of the universal rack power unit 804 and device 806 can be inserted into the rack 802. The universal rack power unit 804 can be, for example, a rack power unit 700 of FIG. 7, a rack power unit 200 of FIG. 2 or a rack power unit 114 of FIG. 1. The device 806 can be, for example, a device 112 of FIG. 1. Although a single universal rack power unit 804 and device 806 are illustrated in additional detail, any number of universal rack power units and/or devices can be housed in rack 802.

Thus, embodiments may provide systems and methods such that a power supply unit for servers and other computer equipment is able to accept a variety of electrical sources that include both AC and DC electricity. Moreover, a plug type is disclosed that can be used for both AC and DC and prevents reverse polarization.

The foregoing diagrams represent logical architectures for describing processes according to some embodiments, and actual implementations may include more or different components arranged in other manners. Other topologies may be used in conjunction with other embodiments. Moreover, each component or device described herein may be implemented by any number of devices in communication via any number of other public and/or private networks. Two or more of such computing devices may be located remote from one another and may communicate with one another via any known manner of network(s) and/or a dedicated connection. Each component or device may comprise any number of hardware and/or software elements suitable to provide the functions described herein as well as any other functions.

Embodiments described herein are solely for the purpose of illustration. Those in the art will recognize other embodiments may be practiced with modifications and alterations to that described above.

What is claimed is:

1. A power supply component for a computer server, comprising:
a physical input receptacle adapted to receive either of both an Alternating Current (“AC”) plug and a Direct Current (“DC”) plug;
an AC-to-DC rectifier circuit coupled to the physical input receptacle to convert AC current into DC current when AC current is received via the physical input receptacle; and
a DC-to-DC voltage regulator to reduce voltages swings.

2. The power supply component of claim 1, wherein the AC-to-DC rectifier circuit senses a lack of AC and allows DC to bypass the rectifier circuit.

3. The power supply component of claim 1, further comprising:
at least one heat sink proximate to the AC-to-DC rectifier circuit.

4. The power supply component of claim 1, wherein the DC-to-DC voltage regulator accommodates voltage swings from a DC source as more current is drawn.

5. The power supply component of claim 1, where the physical input receptacle is adapted to prevent reverse polarization.

6. The power supply component of claim 5, wherein the physical input receptacle is associated with a National Electrical Manufacturers Association (“NEMA”) C19 connector.

7. The power supply component of claim 1, wherein the computer server is associated with a data center.

8. The power supply component of claim 7, wherein the power supply component is within a data center computer server rack.

9. A method, comprising:
receiving current via a physical input receptacle adapted to receive either of both an Alternating Current (“AC”) plug and a Direct Current (“DC”) plug;
when AC current is received via the physical input receptacle, converting, by an AC-to-DC rectifier circuit coupled to the physical input receptacle, AC current into DC current; and
reducing voltage swings via a DC-to-DC voltage regulator.

10. The method of claim 9, wherein the AC-to-DC rectifier circuit senses a lack of AC and allows DC to bypass the rectifier circuit.

11. The method of claim 9, further comprising:
dissipating heat via at least one heat sink proximate to the AC-to-DC rectifier circuit.

12. The method of claim 9, wherein the DC-to-DC voltage regulator accommodates voltage swings from a DC source as more current is drawn.

13. The method of claim 9, where the physical input receptacle is adapted to prevent reverse polarization.

14. The method of claim 13, wherein the physical input receptacle is associated with a National Electrical Manufacturers Association (“NEMA”) C19 connector.

15. The method of claim 1, wherein the computer server is associated with a data center.

16. The method of claim 15, wherein the power supply component is within a data center computer server rack.

17. A computer data center, comprising:
a plurality of device racks, each device rack including a first rack power unit a first plurality of devices, the first rack power unit including:
a physical input receptacle adapted to receive either of both an Alternating Current (“AC”) plug and a Direct Current (“DC”) plug;
an AC-to-DC rectifier circuit coupled to the physical input receptacle to convert AC current into DC current when AC current is received via the physical input receptacle; and
a DC-to-DC voltage regulator to reduce voltages swings.

18. The computer data center of claim 17, wherein the AC-to-DC rectifier circuit senses a lack of AC and allows DC to bypass the rectifier circuit.

19. The computer data center of claim 17, wherein the DC-to-DC voltage regulator accommodates voltage swings from a DC source as more current is drawn.

20. The computer data center of claim 17, where the physical input receptacle is adapted to prevent reverse polarization.
